(19) United States
(12) Patent Application Publication
(10) Pub. No.: US 2026/0344132 A1
(43) Pub. Date: Oct. 29, 2026

(54) SEMICONDUCTOR DEVICE

(71) Applicant: Ennostar Corporation, Hsinchu City (TW)

(72) Inventor: Min-Hsun HSIEH, Hsinchu City (TW)

(21) Appl. No.: 19/656,834

(22) Filed: Apr. 23, 2026

(30) Foreign Application Priority Data
Apr. 25, 2025 (TW) 114115704
Mar. 24, 2026 (TW) 115111191

(51) Int. Cl. H10H 20/855; H10H 20/825; H10H 20/831

(52) U.S. Cl. CPC H10H 20/855; H10H 20/825; H10H 20/8312

(57) ABSTRACT

A semiconductor device includes a semiconductor structure and a first lens. The semiconductor structure includes an active structure, a first-type semiconductor structure, and a second-type semiconductor structure. The first lens includes an intrinsic semiconductor layer and is disposed on the side of the first-type semiconductor structure away from the active structure. The first lens and the first-type semiconductor structure include a same material.

### REFERENCE TO RELATED APPLICATION

This application claims the rights of priorities based on TW Application Serial No. 114115704, filed on Apr. 25, 2025, which claims priority of TW Application Serial No. 115111191, filed on Mar. 24, 2026, and the contents of which are hereby incorporated by references in their entireties.

### TECHNICAL FIELD

The application relates to a semiconductor device, and more particularly to the semiconductor device having a lens.

### DESCRIPTION OF BACKGROUND ART

Light-emitting diodes (LEDs) have characteristics such as low power consumption, low heat generation, long operating life, impact resistance, small size, and fast response speed. Therefore, they are widely used in various fields that require semiconductor devices, such as automotive lighting, home appliances, display devices, and lighting systems. However, although the commercial LEDs can meet their expected functions, they are still not ideal in some applications and the performance can be further improved.

### SUMMARY OF THE APPLICATION

A semiconductor device includes a semiconductor structure and a first lens. The semiconductor structure includes an active structure, and a first-type semiconductor structure and a second-type semiconductor structure respectively disposed on opposite sides of the active structure. The first lens includes an intrinsic semiconductor layer and is disposed on the side of the first-type semiconductor structure away from the active structure. The first lens and the first-type semiconductor structure include a same material.

### BRIEF DESCRIPTION OF THE DRAWINGS

For ease of understanding, the drawings and the detailed descriptions thereof may be referred to concurrently when reading the present disclosure. Through the specific embodiments described herein and with reference to the corresponding drawings, the specific embodiments of the present disclosure are explained in detail to illustrate the operating principles thereof. In addition, for clarity, the features in the drawings may not be depicted to scale; therefore, the dimensions of certain features in some drawings may be intentionally exaggerated or reduced.

FIG. 1 illustrates a cross-sectional view of a semiconductor device according to some embodiments of the present disclosure.

FIGS. 2A and 2B illustrate the top views of the semiconductor device according to some embodiments of the present disclosure, showing only the active structure and the second-type semiconductor structure.

FIGS. 3A, 4A, and FIGS. 5A and 3B, 4B and FIG. 5B illustrate the top and cross-sectional views of the semiconductor device according to some embodiments of the present disclosure, showing only the first lens and the first-type semiconductor structure.

FIGS. 6A and 6B illustrate the top views of the semiconductor device according to some embodiments of the present disclosure.

FIGS. 7, 8, 9, 10, 11, and FIG. 12 illustrate the cross-sectional views of the semiconductor device according to other embodiments of the present disclosure.

FIG. 13 illustrates a cross-sectional view of the semiconductor device according to another embodiment of the present disclosure.

FIGS. 14A, 15A, 16A, and FIGS. 17A and 14B, 15B, 16B, and 17B illustrate the top and cross-sectional views of the semiconductor device according to another embodiment of the present disclosure, showing only the first lens and the first-type semiconductor structure.

FIGS. 18, 21, and 23 illustrate the cross-sectional views of the semiconductor device according to other embodiments of the present disclosure.

FIG. 20 illustrates a top view of the semiconductor device shown in FIG. 18 viewed from the electrode side.

FIGS. 19, 22, 24, and FIG. 25 illustrate the top views of the semiconductor device according to other embodiments of the present disclosure.

FIG. 26 illustrates a luminous intensity distribution diagram of the semiconductor device of the present disclosure.

FIGS. 27A, 27B, 27C, and FIG. 27D illustrate the manufacturing process flowcharts of a first lens according to some embodiments of the present disclosure.

FIGS. 28, 30, and FIG. 31 illustrate the cross-sectional views of the semiconductor device according to some embodiments of the present disclosure.

FIG. 29 illustrates an enlarged view of the semiconductor device according to some embodiments of the present disclosure. The enlarged view of FIG. 29 is taken from a portion C of FIG. 28.

FIG. 32 illustrates a top view of the semiconductor device according to some embodiments of the present disclosure.

FIG. 33 illustrates a schematic diagram of a light-emitting module according to other embodiments of the present disclosure.

FIG. 34 illustrates a schematic diagram of a light-emitting apparatus according to other embodiments of the present disclosure.

### DETAILED DESCRIPTION OF PREFERRED EMBODIMENTS

The present disclosure provides several different embodiments that may be used to implement various features of the present disclosure. For the sake of simplicity, the present disclosure also describes examples of specific components and arrangements. The purpose of providing these embodiments is merely illustrative and is not intended to impose any limitation. Various embodiments in the present disclosure may use repeated reference numerals and/or textual annotations. The use of such repeated reference numerals and annotations is intended to make the description more concise and clear, and is not intended to indicate any relationship between different embodiments and/or configurations.

In addition, spatially relative terms used in the present disclosure, such as “under”, “lower”, “below”, “above”, “on”, “upper”, “top”, “bottom”, and similar terms, are used for ease of description to describe the relative relationship between one element or feature and another (or multiple) element(s) or feature(s) in the figures. Apart from the orientation shown in the figures, these spatially relative terms are also used to describe the orientation of the elements in use and during operation. As the orientation of the element changes (e.g., rotated by 90 degrees or to other orientations), the corresponding spatial descriptions are to be interpreted in a similar manner.

Although the present disclosure uses the terms first, second, third, and so forth to describe elements, components, regions, layers, and/or sections, it should be understood that such elements, components, regions, layers, and/or sections are not to be limited by these terms. These terms are only used to distinguish one element, component, region, layer, and/or section from another, and do not imply any sequential order, nor do they indicate the arrangement order between the elements or the sequence in manufacturing processes. Therefore, without departing from the scope of the specific embodiments of the present disclosure, an element, component, region, layer, or section described as “first” herein may also be referred to as a “second” element, component, region, layer, or section.

The terms “about” or “substantially” as referred to in the present disclosure generally indicate within 20% of a given value or range, preferably within 10%, more preferably within 5%, or within 3%, 2%, 1%, or 0.5%. It should be noted that the numerical values provided in the specification are approximate values, meaning that even in the absence of explicit use of the terms “about” or “substantially,” such meanings may be implied.

The terms “coupled,” “coupling,” or “electrically connected” as referred to in the present disclosure include any direct or indirect electrical connection means. For example, when the text describes a first component as being coupled to a second component, it means that the first component may be directly electrically connected to the second component, or indirectly electrically connected to the second component via other devices or connecting means.

Although the following description of the present disclosure is provided using specific embodiments, the principles of the present disclosure may also be applied to other embodiments. Furthermore, to avoid obscuring the spirit of the present invention, certain details are omitted, and such omitted details fall within the knowledge of those skilled in the relevant art.

Unless otherwise specified, in the disclosure, the general formula InGaP represents Inₓ₀Ga(₁₋ₓ₀ ₎P, wherein 0≤x0≤1; the general formula AlInP represents Alₓ₁In₍₁₋ₓ₁₎P, wherein 0≤x1≤1; the general formula AlGaInP represents Alₓ₂Gaₓ₃In₍₁₋ₓ₂₋ₓ₃₎P, wherein 0≤x2≤1 and 0≤x3≤1; the general formula InGaAsP represents Inₓ₄Ga₍₁₋ₓ₄₎Asₓ₅P₍₁₋ₓ₅₎, wherein 0≤x4≤1 and 0≤x5≤1; the general formula AlGaInAs represents Alₓ₆Gaₓ₇In₍₁₋ₓ₆₋ₓ₇₎As, wherein 0≤x6≤1, 0≤x7≤1; the general formula InGaNAs represents Inₓ₈Ga₍₁₋ₓ₈₎Nₓ₉As₍₁₋ₓ₉₎, wherein 0≤x8≤1, 0≤x9≤1; the general formula InGaAs represents Inₓ₁₀Ga₍₁₋ₓ₁₀₎As, wherein 0≤x10≤1; the general formula AlGaAs represents Alₓ₁₁Ga₍₁₋ₓ₁₁₎As, wherein 0≤x11≤1; the general formula InGaN represents Inₓ₁₂Ga₍₁₋ₓ₁₂₎N, wherein 0≤x12≤1; the general formula AlGaN represents Alₓ₁₃Ga₍₁₋ₓ₁₃₎N, wherein 0≤x13≤1; the general formula InAlGaN represents Inₓ₁₄Alₓ₁₅Ga₍₁₋ₓ₁₄₋ₓ₁₅₎N, wherein 0≤x14≤1, 0≤x15≤1. The content of each element can be adjusted for different purposes, such as, but not limited to, adjusting the bandgap, the domain wavelength or the peak wavelength of the semiconductor device.

The semiconductor device disclosed herein may be, for example, a light-emitting diode or a laser diode. The composition and the dopant of each layer of the semiconductor device disclosed herein can be analyzed by any suitable method, such as secondary ion mass spectrometer (SIMS). In addition, the thickness of each layer can also be analyzed by any suitable method, such as transmission electron microscopy (TEM) or scanning electron microscopy (SEM).

The disclosure provides a semiconductor device with a lens. The lens arrangement optimizes the optical profile of the semiconductor device to improve the emission angle (e.g., narrowing the emission angle). The first lens and the first-type semiconductor structure include the same material to reduce the optical loss caused by the Fresnel reflection and improve the light extraction efficiency (LEE). Furthermore, the first lens and/or the second lens can further focus or collimate the light emitted from the active structure.

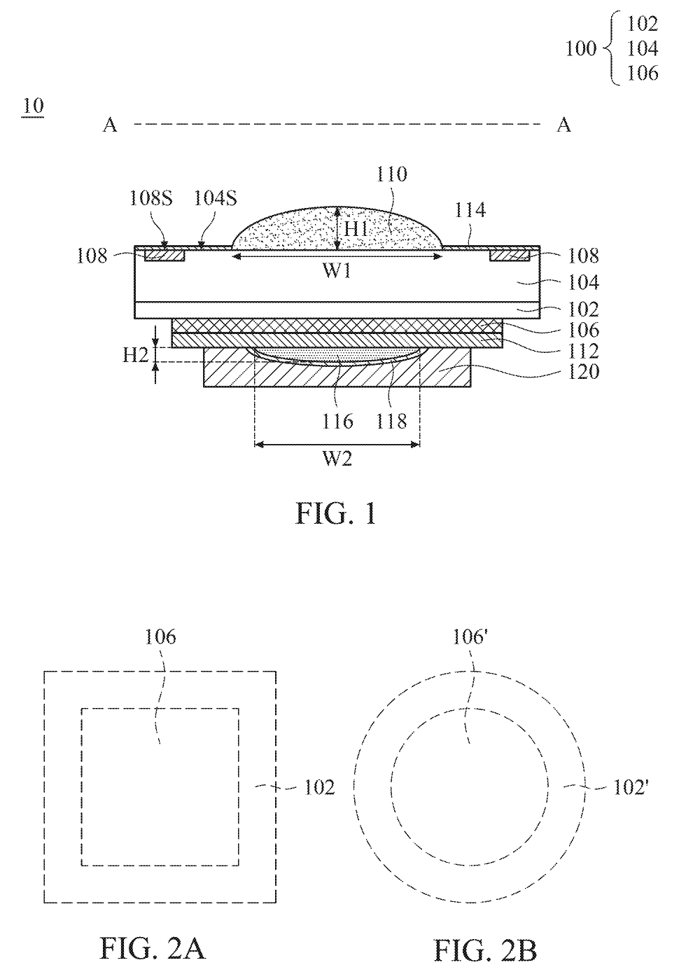

FIG. 1 illustrates a cross-sectional view of a semiconductor device 10 according to some embodiments of the present disclosure. The semiconductor device 10 includes a semiconductor structure 100 (including a first-type semiconductor structure 104, an active structure 102, and a second-type semiconductor structure 106) and a first lens 110. The first lens 110 includes an intrinsic semiconductor material or doped material.

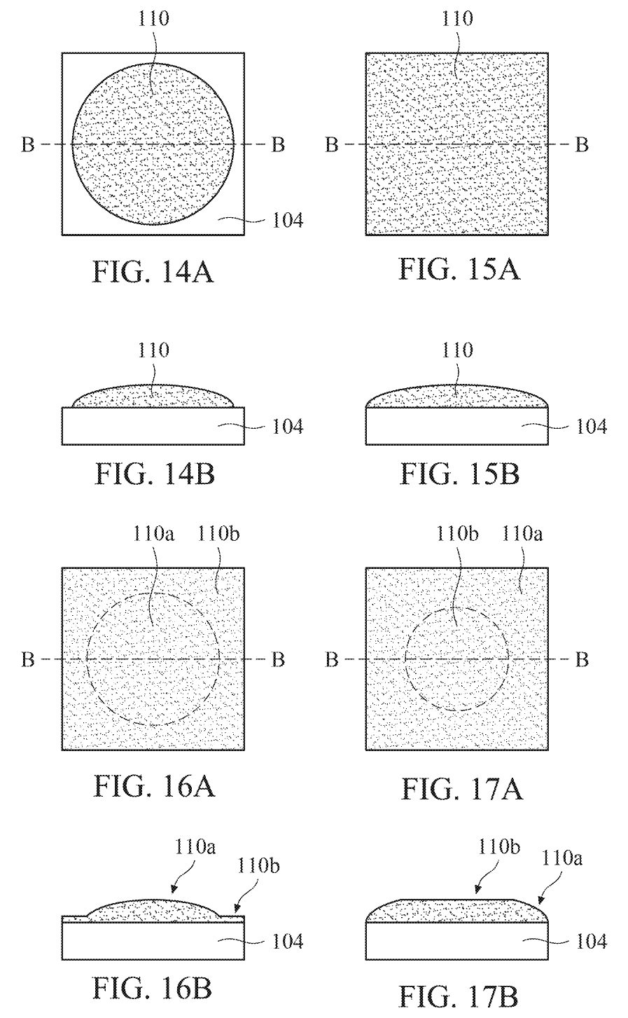

In the embodiment, the semiconductor device 10 is a light-emitting device, and the main light-emitting surface of the semiconductor device 10 is located on the side of the first-type semiconductor structure 104 away from the active structure 102. In other embodiments, the main light-emitting surface of the semiconductor device is located on the side of the second-type semiconductor structure 106 away from the active structure 102, such as the semiconductor device 20 shown in FIG. 10, which will be described in detail later. In the embodiment, the semiconductor device 10 is a vertical chip, with the contact electrode 108 and the second electrode 120 formed on opposite sides of the semiconductor structure 100 and electrically connected to the first-type semiconductor structure 104 and the second-type semiconductor structure 106, respectively. In other embodiments, the semiconductor device is a flip chip, such as the semiconductor device 40 shown in FIG. 13, which will be described in detail later.

Referring to FIG. 1, in some embodiments, the semiconductor structure 100 includes a second-type semiconductor structure 106, an active structure 102, and a first-type semiconductor structure 104 stacked vertically in sequence. The active structure 102 is located on the second-type semiconductor structure 106, and the first-type semiconductor structure 104 is located on the active structure 102. As shown in FIG. 1, the active structure 102 is disposed between the first-type semiconductor structure 104 and the second-type semiconductor structure 106, and the first-type semiconductor structure 104 and the second-type semiconductor structure 106 are in direct contact with opposite sides of the active structure 102.

The first-type semiconductor structure 104 includes a first conductivity type, while the second-type semiconductor structure 106 includes a second conductivity type different from the first conductivity type. For example, the first conductivity type is n-type and the second conductivity type is p-type. Alternatively, the first conductivity type is p-type and the second conductivity type is n-type. Thus, the first-type semiconductor structure 104 and the second-type semiconductor structure 106 respectively provide electrons and holes or holes and electrons. In some embodiments, the conductivity types of the first-type semiconductor structure 104 and the second-type semiconductor structure 106 can be adjusted by doping. The dopant includes an element selected from Group II, Group IV, or Group VI of the periodic table, such as carbon (C), zinc (Zn), silicon (Si), germanium (Ge), tin (Sn), selenium (Se), magnesium (Mg), or tellurium (Te).

In some embodiments, the first-type semiconductor structure 104, the active structure 102, and the second-type semiconductor structure 106 respectively include a III-V group semiconductor material. The III-V group semiconductor material includes aluminum (Al), gallium (Ga), indium (In), arsenic (As), phosphorus (P), or nitrogen (N). The first-type semiconductor structure 104, the active structure 102, and the second-type semiconductor structure 106 may not include nitrogen (N). Specifically, the III-V group semiconductor material includes a binary compound semiconductor (e.g., GaAs, GaP, or GaN), a ternary compound semiconductor (e.g., InGaAs, AlGaAs, InGaP, AlInP, InGaN, or AlGaN), or a quaternary compound semiconductor (e.g., AlGaInAs, AlGaInP, AlInGaN, InGaAsP, InGaNAs, or AlGaAsP). In the embodiment, the first-type semiconductor structure 104 is n-type gallium nitride (n-GaN) and the second-type semiconductor structure 106 is p-type gallium nitride (p-GaN).

The semiconductor device 10 includes a double heterostructure (DH), a double-side double heterostructure (DDH), or a multiple quantum well (MQW) structure. In some embodiments, when the semiconductor device 10 is operated under an electric current, the active structure 102 can emit light. The light includes the visible light or the invisible light. The light emitted from the semiconductor device 10 is dependent with the material composition of the active structure 102. For example, when the material of the active structure 102 includes AlGaN, an ultraviolet light with a peak wavelength of 250 nm to 400 nm is provided; when the material of the active structure 102 includes InGaN, a deep blue or blue light with a peak wavelength of 400 nm to 490 nm, or a green or yellow light with a peak wavelength of 490 nm to 550 nm, or a red light with a peak wavelength of 560 nm to 650 nm is provided; when the material of the active structure 102 includes InGaP or AlGaInP, a yellow, orange, or red light with a peak wavelength of 530 nm to 700 nm is provided; when the material of the active structure 102 includes InGaAs, InGaAsP, AlGaAs, or AlGaInAs, an infrared light with a peak wavelength of 700 nm to 1700 nm is provided.

FIGS. 1 and 2A to 2B further illustrate the configuration of the active structure 102 and the second-type semiconductor structure 106. FIGS. 2A and 2B illustrate the top views of the semiconductor device 10 according to some embodiments of the present disclosure, showing only the active structure 102 and the second-type semiconductor structure 106. In some embodiments, the active structure 102 and the second-type semiconductor structure 106 include the same profile; for example, both the active structure 102 and the second-type semiconductor structure 106 include a rectangular profile (FIG. 2A), or both the active structure 102' and the second-type semiconductor structure 106' include a circular profile (FIG. 2B). In other embodiments, the active structure 102 includes a profile different from that of the second-type semiconductor structure 106.

Referring to FIG. 1, in some embodiments, a first lens 110 is disposed on the side of the first-type semiconductor structure 104 away from the active structure 102. Specifically, the first lens 110 is located on and in direct contact with the first-type semiconductor structure 104. The first lens 110 is configured to focus or collimate the light emitted from the active structure 102 and optimize the optical profile of the semiconductor device 10 to improve the emission angle (e.g., narrow the emission angle). In some embodiments, the first lens 110 includes a curved profile, a maximum height H1, and a maximum width W1. A ratio of the maximum height H1 to the maximum width W1 is between 1:5 and 1:15. In some embodiments, specifically, the first lens 110 includes a convex profile, the maximum height H1 of 1~5 µm (e.g., 3 µm), and the maximum width W1 of 5~15 µm (e.g., 10 µm). Within the above size range, the semiconductor device 10 includes a desired emission angle; for example, in the emission intensity distribution curve of the semiconductor device 10, the angle of the semiconductor device 10 at 50% of the emission intensity is +45° to -45°. In some embodiments, the first lens 110 includes the same material as the first-type semiconductor structure 104. For example, in an embodiment, when the first-type semiconductor structure 104 includes gallium nitride, the first lens 110 includes undoped semiconductor material such as undoped gallium nitride (u-GaN). In an embodiment, when the first-type semiconductor structure 104 includes aluminum gallium nitride, the first lens 110 includes undoped aluminum gallium nitride (u-AlGaN). The first lens 110 and the first-type semiconductor structure 104 include the same material to reduce the optical loss caused by the Fresnel reflection and improve the light extraction efficiency (LEE).

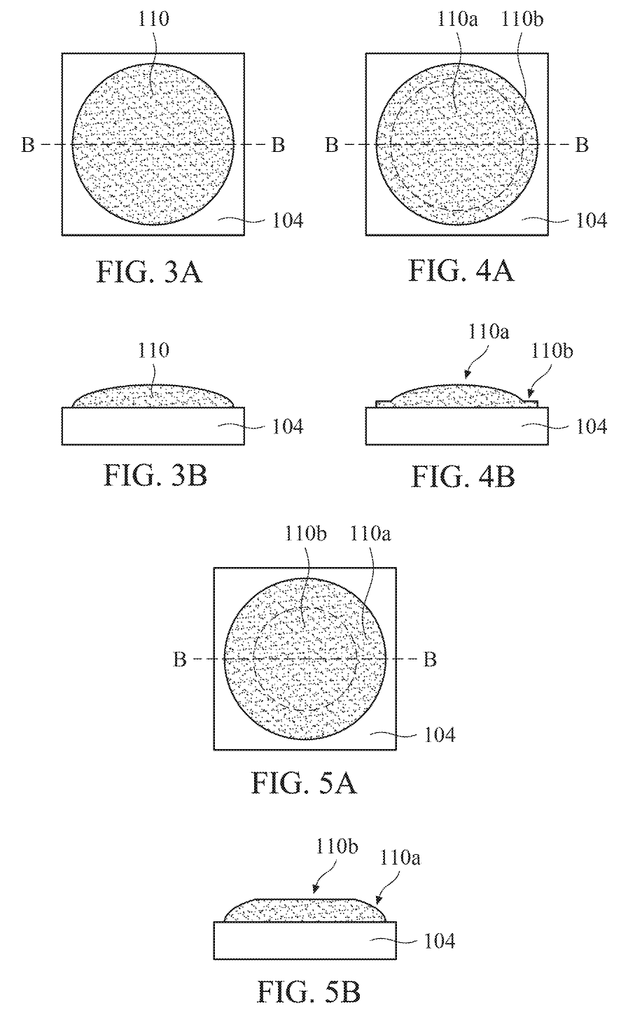

FIGS. 1, 3A~5A, and 3B~5B further illustrate the configuration of the first lens 110 of the vertical type semiconductor device. FIGS. 3A, 4A, and 5A illustrate the top views of the semiconductor device 10 according to some embodiments of the disclosure, showing only the first lens 110 and the first-type semiconductor structure 104. FIGS. 3B, 4B, and 5B respectively illustrate the cross-sectional views alone the line B-B of FIGS. 3A, 4A, and 5A. In some embodiments, the first lens 110 includes a curved (convex) profile, as shown in FIGS. 3A and 3B. In other embodiments, the first lens 110 includes a first portion 110a including a curved surface, a second portion 110b including a flat surface, and the second portion 110b surrounds the first portion 110a, as shown in FIGS. 4A and 4B. Alternatively, the first lens 110 includes a first portion 110a including a curved surface, and the second portion 110b including a flat surface is surrounded by the first portion 110a, as shown in FIGS. 5A and 5B. Therefore, the design of the first lens 110 can be modified according to the light-emitting characteristics of the semiconductor device 10 to obtain a desired optical profile and emission angle. In the embodiments, the first lens 110, the first portion 110a, and the second portion 110b include a circular profile in the top view; in other embodiments, the first lens 110, the first portion 110a, and the second portion 110b may include a rectangular profile in the top view.

In some embodiments, as shown in FIG. 1, the semiconductor device 10 optionally includes a first conductive layer 114, a second conductive layer 112, a second lens 116, and/or a reflective layer 118. In some embodiments, the contact electrode 108, the first conductive layer 114, the second conductive layer 112, the reflective layer 118, and the second electrode 120 can be formed by, for example, chemical vapor deposition (CVD) or physical vapor deposition (PVD) processes.

In some embodiments, the contact electrode 108 is selectively formed between the first conductive layer 114 and the first-type semiconductor structure 104. In some embodiments, the contact electrode 108 is continuously disposed on a periphery of the first lens 110. As shown in FIG. 1, a plurality of contact electrodes 108 is discontinuously disposed on the periphery of the first lens 110 (e.g., on two sides of the first lens 110) and is spaced apart from the first lens 110. In the embodiment, the contact electrode 108 is embedded in the first-type semiconductor structure 104 to electrical contact (e.g., ohmic contact) the first-type semiconductor structure 104. The top surface 108S of the contact electrode 108 is flush with the top surface 104S of the first-type semiconductor structure 104. In another embodiment, the top surface 108S of the contact electrode 108 may be lower or higher than the top surface 104S of the first-type semiconductor structure 104. The contact electrode 108 is configured as a current path for supplying power from an external power source to the first-type semiconductor structure 104. In some embodiments, the contact electrode 108 includes a single-layer or multi-layer metal structure, the metal structure includes the metal such as nickel (Ni), titanium (Ti), platinum (Pt), palladium (Pd), silver (Ag), gold (Au), aluminum (Al), copper (Cu), chromium (Cr), or an alloy of the above metals.

In the embodiment, the first lens 110 has a first area in the top view, the first-type semiconductor structure 104 has a second area in the top view, and the first area is smaller than the second area, so that the contact electrode 108 can be disposed on the periphery of the first lens 110 without overlapping with the first lens 110. In this way, the light blocking caused by the contact electrode 108 to the semiconductor device 10 can be reduced. In the embodiment, an accommodating space is formed in the first-type semiconductor structure 104 by the photolithography process and the etching process where the contact electrode 108 is to be formed. Then, a contact electrode material layer (not shown) is filled into the accommodating space. After the excess contact electrode material layer is removed by a planarization process, the remaining contact electrode material layer is formed as the contact electrode 108.

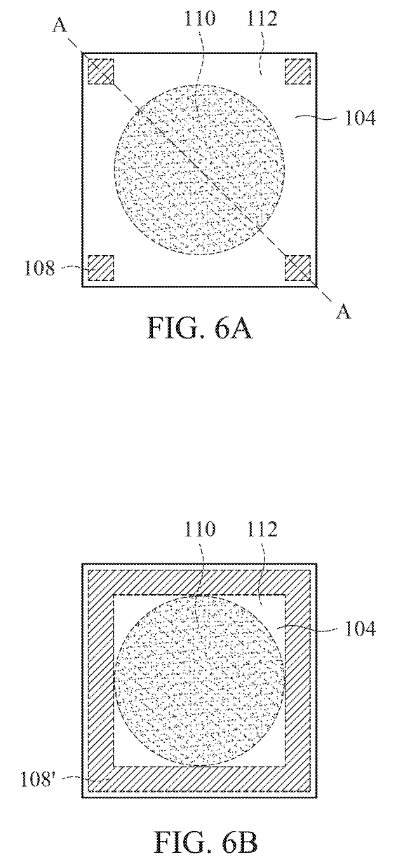

Please refer to FIG. 1 and FIG. 6A~ FIG. 6B for further explanation of the distribution configuration of the contact electrode 108. FIG. 6A~ FIG. 6B illustrate the top views of a part of the elements of the semiconductor device 10 according to some embodiments of the disclosure. FIG. 1 illustrates the cross-sectional view along the line A-A in FIG. 6A. As shown in FIG. 6A, in some embodiments, a plurality of (e.g., four) contact electrodes 108 is formed around the first lens 110 and overlaps with the first-type semiconductor structure 104 . The number, size, and arrangement of the contact electrodes 108 can be set according to the design requirement. In other embodiments, as shown in FIG. 6B, the contact electrodes 108 ' continuously surrounds the first lens 110 and includes an annular shape (e.g., a rectangular annular shape or a square shape).

Referring to FIG. 1, in some embodiments, the second electrode 120 is disposed on the side of the first-type semiconductor structure 104 or the second-type semiconductor structure 106 away from the active structure 102. For example, the second electrode 120 may be disposed on the side of the second-type semiconductor structure 106 away from the active structure 102 and electrically connected to the second-type semiconductor structure 106, as shown in FIG. 1. Alternatively, the second electrode 120 may be disposed on the side of the first-type semiconductor structure 104 away from the active structure 102 and electrically connected to the first-type semiconductor structure 104, as shown in FIG. 10. This part will be described in detail later. Referring to FIG. 1, the second electrode 120 and the first lens 110 are disposed on opposite sides of the semiconductor structure 100. The second electrode 120 is configured to serve as a current path for supplying power from an external power source to the second-type semiconductor structure 106. In some embodiments, the material of the second electrode 120 includes a metal, such as chromium (Cr), titanium (Ti), tungsten (W), gold (Au), aluminum (Al), indium (In), tin (Sn), nickel (Ni), copper (Cu), rhodium (Rh), platinum (Pt), silver (Ag), or an alloy of the above metals.

In some embodiments, the second conductive layer 112 is disposed on the side of the second-type semiconductor structure 106 away from the active structure 102 and connected to the second-type semiconductor structure 106. As shown in FIG. 1, the second conductive layer 112 is disposed between the second-type semiconductor structure 106 and the second electrode 120. In some embodiments, a contact electrode may be selectively disposed between the second-type semiconductor structure 106 and the second conductive layer 112. On the other hand, the first conductive layer 114 is disposed around the first lens 110 and covers the contact electrode 108 and the first-type semiconductor structure 104. The second conductive layer 112 and the first conductive layer 114 are configured to diffuse the electrical current and form the ohmic contact with the second-type semiconductor structure 106 and the first-type semiconductor structure 104, respectively. The second conductive layer 112 and the first conductive layer 114 include the transparent conductive layers or are transparent to the light emitted from the active structure 102, for example, including a transmittance of 80% or more. In some embodiments, the materials of the second conductive layer 112 and the first conductive layer 114 include metal oxide or thin metal having a thickness less than 500 angstroms (Å). The metal includes, but is not limited to, gold (Au) and nickel/gold (Ni/Au). The metal oxide includes, but is not limited to, indium tin oxide (ITO), aluminum zinc oxide (AZO), gallium doped zinc oxide (GZO), zinc oxide (ZnO), or indium zinc oxide (IZO).

The semiconductor device 10 optionally further includes a second lens 116. The second lens 116 and the first lens 110 are disposed on opposite sides of the semiconductor structure 100. In some embodiments, the second lens 116 is embedded in the second electrode 120 and covers the second conductive layer 112. The second lens 116 is configured to further focus or collimate the light emitted from the active structure 102. In some embodiments, the second lens 116 includes a curved profile, a maximum height H2, and a maximum width W2. A ratio of the maximum height H2 to the maximum width W2 is between 1:5 and 1:15. In some embodiments, specifically, the second lens 116 includes a convex profile, a maximum height H2 of 1~5 µm (e.g., 3 µm), and a maximum width W2 of 5~15 µm (e.g., 10 µm). Within the above size range, the semiconductor device 10 includes a desired emission angle. The dimensions of the first lens 110 and the second lens 116 may be the same or different; for example, the size of the first lens 110 may be larger or smaller than the size of the second lens 116. In the embodiment, the second lens 116 includes an insulating material, such as titanium oxide, silicon nitride, silicon oxide, or a combination of the above materials. In other embodiments, the second lens 116 may include an intrinsic semiconductor material or a doped semiconductor material. In other embodiments, the second lens 116 includes a metallic material or a transparent conductive material. In other words, the first lens 110 and the second lens 116 may include the same or different materials.

In some embodiments, the reflective layer 118 covers or conforms to the second lens 116 and is embedded in the second electrode 120. The reflective layer 118 is configured to reflect the light emitted from the semiconductor structure 100 (e.g., the light emitted from the active structure 102) toward the first-type semiconductor structure 104, and outwardly from the semiconductor structure 100. In the embodiment, the material of the reflective layer 118 includes a metal, such as aluminum (Al), gold (Au), platinum (Pt), zinc (Zn), silver (Ag), nickel (Ni), germanium (Ge), indium (In), tin (Sn), or an alloy of the above materials.

As shown in FIG. 1, the present disclosure optimizes the optical profile of the semiconductor device 10 by means of the first lens 110, thereby improving the emission angle (e.g., narrowing the emission angle). Furthermore, the first lens 110 and the first-type semiconductor structure 104 include the same material, which reduces the optical loss caused by the Fresnel reflection and improves the light extraction efficiency (LEE). Moreover, the first lens 110 and/or the second lens 116 can further focus or collimate the light emitted from the active structure 102.

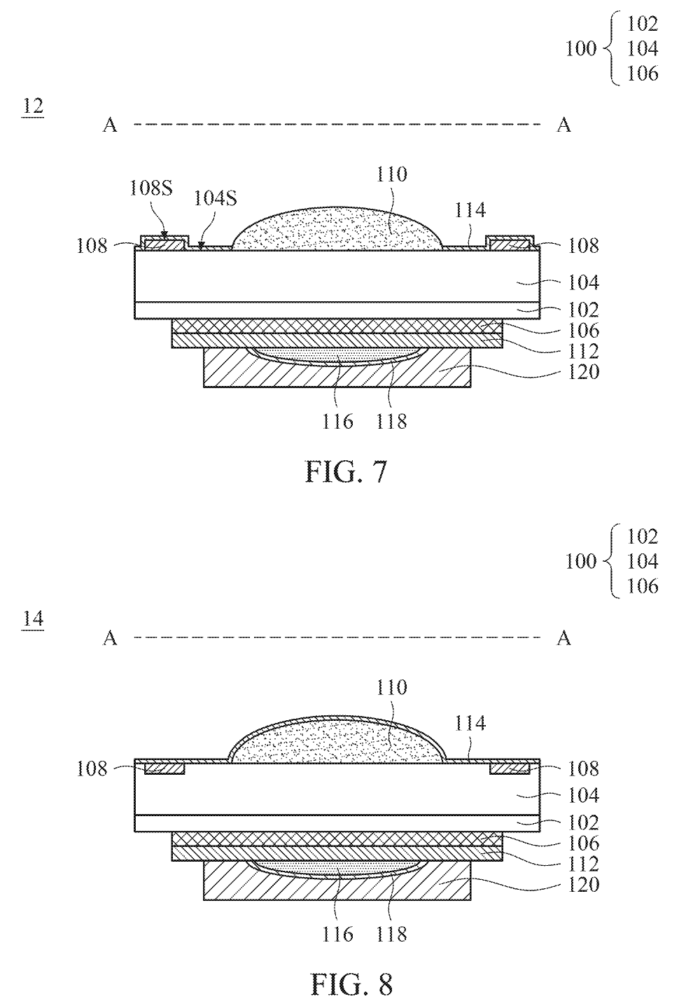

FIGS. 7~12 illustrate the cross-sectional views of the semiconductor devices 12, 14, 16, 20, 22, and 30, respectively, according to other embodiments of the present disclosure.

The semiconductor device 12 in FIG. 7 is similar to the semiconductor device 10 in FIG. 1, except that the contact electrode 108 is disposed above the top surface 104S of the first-type semiconductor structure 104, and the first conductive layer 114 covers or conformally covers the top surface 108S of the contact electrode 108 and all sidewalls of the contact electrode 108. In this way, the process step of forming the accommodating space in the first-type semiconductor structure 104 can be omitted, thereby simplifying the process and reducing the manufacturing costs.

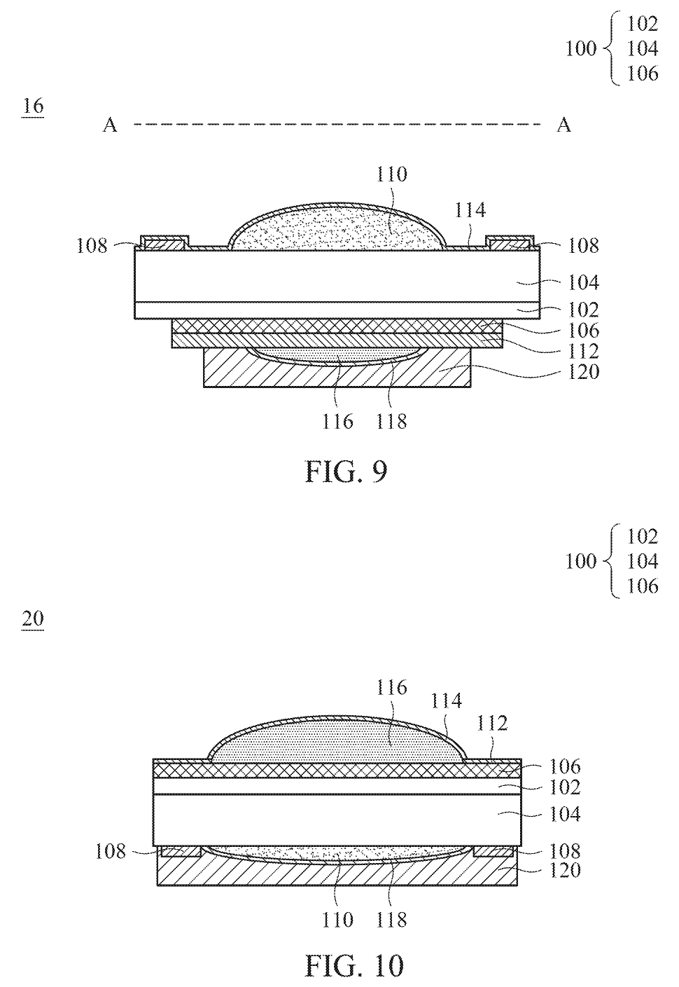

The semiconductor devices 14 and 16 in FIGS. 8 and 9 are similar to the semiconductor device 10 in FIG. 1 and the semiconductor device 12 in FIG. 7, respectively. The difference is that the first conductive layer 114 extends to cover the first lens 110. In other words, the first conductive layer 114 completely covers the first-type semiconductor structure 104, the contact electrode 108, and the first lens 110. In this way, the electrical current can be uniformly diffused into the semiconductor structure 100.

The semiconductor device 20 in FIG. 10 is similar to the semiconductor device 12 in FIG. 7, except that the main light-emitting surface of the semiconductor device 20 is located on the side of the second-type semiconductor structure 106 away from the active structure 102, thus the relative positions of the elements are changed. Specifically, the second lens 116 directly contacts the second-type semiconductor structure 106, the second conductive layer 112 is disposed on the second-type semiconductor structure 106 and surrounds the second lens 116, and/or the first conductive layer 114 covers or conformally covers the second lens 116, the reflective layer 118 covers or conformally covers the first lens 110, and the second electrode 120 is disposed on the side of the first-type semiconductor structure 104 away from the active structure 102 and is electrically connected to the first-type semiconductor structure 104. Therefore, the contact electrode 108, the first lens 110, and the reflective layer 118 are embedded in the second electrode 120.

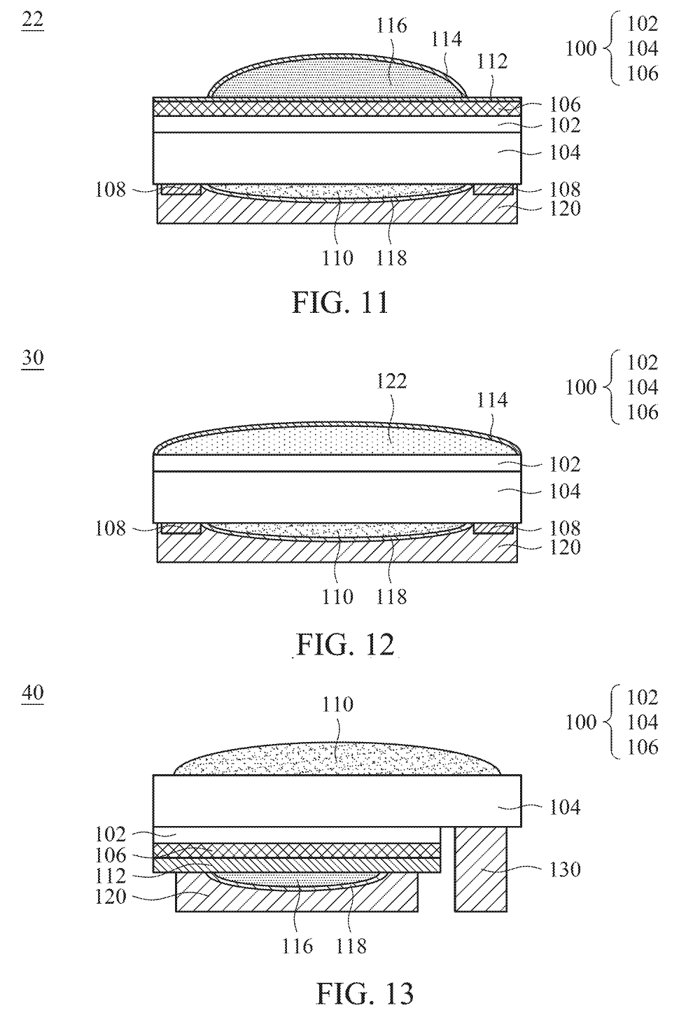

The semiconductor device 22 in FIG. 11 is similar to the semiconductor device 20 in FIG. 10, except that the second conductive layer 112 completely covers the second-type semiconductor structure 106, and the second lens 116 is disposed on the second conductive layer 112. In other words, a portion of the second conductive layer 112 is disposed between the second-type semiconductor structure 106 and the second lens 116. In this way, the electrical current can be uniformly diffused into the semiconductor structure 100.

Because the thickness of the second-type semiconductor structure 106 is smaller than that of the first-type semiconductor structure 104, the active structure 102 shown in FIGS. 10 and 11 is closer to the main light-emitting surface than the active structures 102 shown in FIGS. 7-9 to the main light-emitting surface. The light emitted from the active structure 102 may undergo less internal reflection and scattering, such that the light emission angles of the semiconductor devices 20 and 22 shown in FIGS. 10 and 11 can be greater than those of the semiconductor devices 12, 14, and 16 shown in FIGS. 7~9. In other words, the light beam emitted from the semiconductor devices 12, 14, and 16 shown in FIGS. 7-9 may be more concentrated. Furthermore, the active structure 102 shown in FIGS. 10 and 11 is disposed closer to the main light-emitting surface than the active structures 102 shown in FIGS. 7-9 to the main light-emitting surface. The light from the active structure 102 passes through less medium, the light absorption and scattering are reduced. The light extraction efficiency of the semiconductor devices 20 and 22 shown in FIGS. 10 and 11 can be greater than that of the semiconductor devices 12, 14 and 16 shown in FIGS. 7~9.

The semiconductor device 30 shown in FIG. 12 is similar to the semiconductor device 20 shown in FIG. 10, except that the semiconductor device 30 does not include the second conductive layer 112, and the second-type semiconductor structure 106 shown in FIG. 10 is patterned to form a third lens 122 in FIG. 12, and the first conductive layer 114 covers the third lens 122. In some embodiments, the contact electrodes can be selectively disposed between the first conductive layer 114 and the third lens 122. In the embodiment, the third lens 122 may include a doped semiconductor material (e.g., a III-V group semiconductor material). In other words, the first lens 110 and the third lens 122 may include the same or different semiconductor materials. Since the third lens 122 includes the semiconductor material, the third lens 122 can completely cover the active structure 102 without disposing additional electrodes around the third lens 122.

FIG. 13 illustrates the cross-sectional view of a semiconductor device 40 according to some embodiments of the present disclosure. The semiconductor device 40 shown in FIG. 13 is similar to the semiconductor device 10 shown in FIG. 1, except that the semiconductor device 40 is a flip chip. Therefore, the semiconductor device 40 does not include the contact electrode 108 and the first conductive layer 114 shown in FIG. 1. Instead, a first electrode 130 and a second electrode 120 are disposed on the same side of the semiconductor structure 100. The first electrode 130 and the second electrode 120 are electrically connected to the first-type semiconductor structure 104 and the second-type semiconductor structure 106, respectively, to serve as current paths for supplying power to the first-type semiconductor structure 104 and the second-type semiconductor structure 106 from the external power source. The material and formation method of the first electrode 130 can be referred to the second electrode 120 described in FIG. 1 and will not be repeated here for simplicity.

Please refer to FIGS. 13, 14A-17A, and FIGS. 14B-17B for further illustration of the configuration of the first lens 110 in the flip-chip device. FIGS. 14A-17A illustrate the top views of the semiconductor device 40 according to some embodiments of the disclosure, showing only the first lens 110 and the first-type semiconductor structure 104. FIGS. 14B-17B illustrate the cross-sectional views alone the line B-B of FIGS. 14A-17A, respectively.

In some embodiments, the first lens 110 includes a circular profile in the top view and a curved profile in the cross-sectional view, as shown in FIGS. 14A and 14B. Alternatively, the first lens 110 includes a rectangular profile in the top view and a curved profile in the cross-sectional, as shown in FIGS. 15A and 15B. In some embodiments, the first lens 110 may include a first portion 110a including a curved surface and a second portion 110b including a flat surface, and the second portion 110b surrounds the first portion 110a, as shown in FIGS. 16A and 16B. Alternatively, the first portion 110a of the first lens 110 with the curved surface may surround the second portion 110b having the flat surface, as shown in FIGS. 17A and 17B. Therefore, the design of the first lens 110 can be modified according to the light-emitting characteristics of the semiconductor device 40 to obtain the desired optical profile and emission angle. Although FIGS. 16A and 17A illustrate an example that the first lens 110 completely covers the first-type semiconductor structure 104, the first lens 110 may only cover a portion of the first-type semiconductor structure 104. In the embodiment, the first area of the first lens 110 is less than or equal to the second area of the first-type semiconductor structure 104 in the top view. The electrical current passes through the first-type semiconductor structure 104 and the second-type semiconductor structure 106 via the first electrode 130 and the second electrode 120 disposed on the same side of the semiconductor structure 100, thereby the active structure 102 can emit the light.

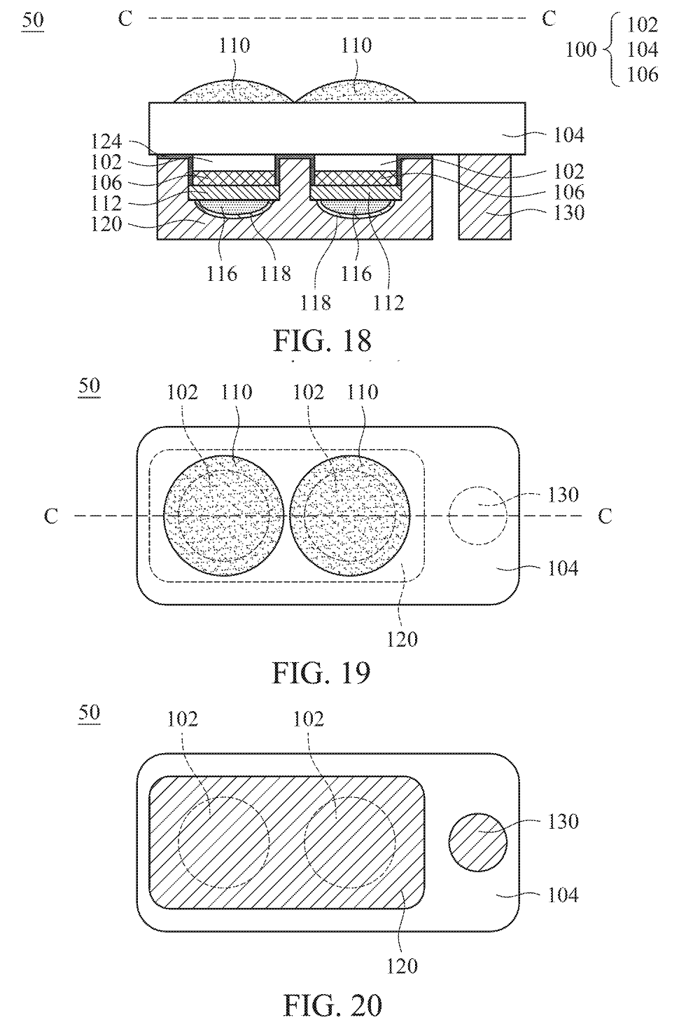

FIGS. 18, 21, and 23 illustrate the cross-sectional views of the semiconductor devices 50, 52, and 54, respectively, according to some embodiments of the present disclosure. FIGS. 19 and 22 illustrate the top views of the semiconductor devices 50 and 52, respectively. FIGS. 24 and 25 illustrate the top views of semiconductor device 54. FIGS. 18, 21, and 23 illustrate the cross-sectional views along the line C-C in FIGS. 19, 22, and 24, respectively.

As shown in FIGS. 18 and 19, the semiconductor device 50 shown in FIG. 18 is similar to the semiconductor device 40 shown in FIG. 13. The main difference is that the semiconductor device 50 includes a plurality of active structures 102, a plurality of second-type semiconductor structures 106, a plurality of second conductive layers 112, a plurality of second lenses 116, a plurality of reflective layers 118, and a plurality of first lenses 110. As shown in FIG. 18, the plurality of active structures 102 are arranged side by side on the same side of the first-type semiconductor structure 104. The plurality of active structures 102 and the plurality of first lenses 110 are arranged on opposite sides of the first-type semiconductor structure 104. The plurality of first lenses 110 is arranged corresponding to the plurality of active structures 102. The light emitted from each active structure 102 can be focused or collimated by the corresponding first lens 110. In some embodiments, the insulating layer 124 covers multiple sidewalls of the active structure 102 and the second-type semiconductor structure 106, and forms between the second electrode 120 and the first-type semiconductor structure 104. The insulating layer 124 is provided to electrically isolate the second electrode 120 from the first-type semiconductor structure 104. The material of the insulating layer 124 includes a dielectric material, such as aluminum oxide (AlOₓ), silicon oxide (SiOₓ), titanium oxide (TiOₓ), silicon nitride (SiNₓ), or a combination thereof.

In the embodiment, the semiconductor device 50 includes the reflective layer 118 disposed on each of the second-type semiconductor structures 106 to reflect the light emitted from each active structure 102 towards the first-type semiconductor structure 104. As shown in FIG. 19, the plurality of first lenses 110 respectively covers the plurality of active structures 102. The plurality of first lenses 110 and the plurality of active structures 102 form a one-to-one configuration. FIG. 20 illustrates the bottom view of the semiconductor device 50 of FIG. 18 viewed from the side of the electrodes (e.g., the first electrode 130 and the second electrode 120). As shown in FIG. 20, the second electrode 120 includes a rectangular profile and completely covers the plurality of active structures 102, and the first electrode 130 includes a circular profile.

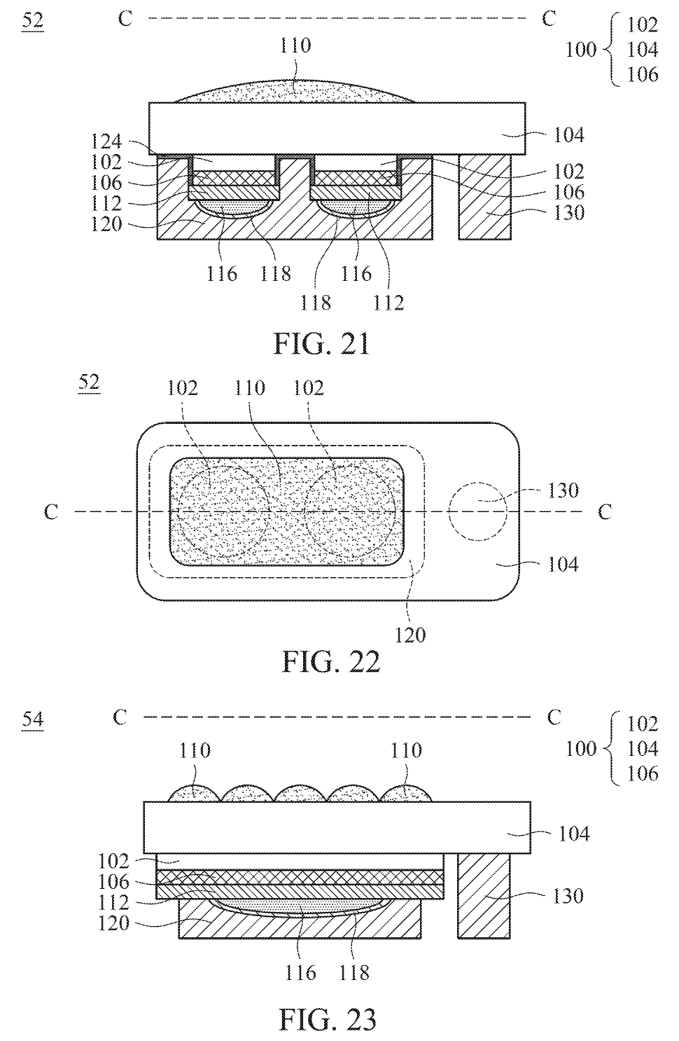

As shown in FIGS. 21 and 22, the semiconductor device 52 in FIG. 21 is similar to the semiconductor device 50 in FIG. 18, except that the first lens 110 shown in FIG. 21 covers a plurality of active structures 102. As shown in FIG. 22, the first lens 110 continuously covers the plurality of active structures 102 mutually separated from each other. In the way, the light emitted by each active structure 102 can be focused or collimated by a single first lens 110, which reduces the process complexity.

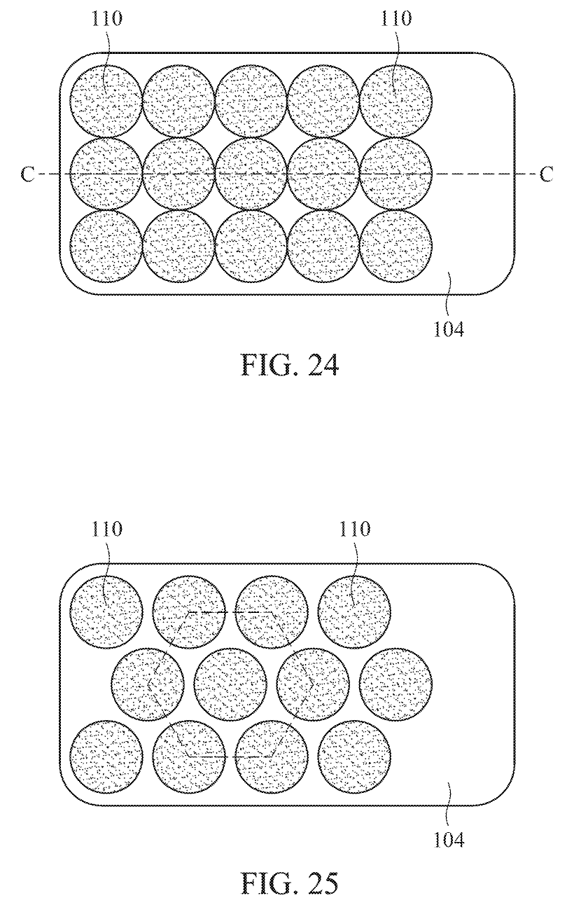

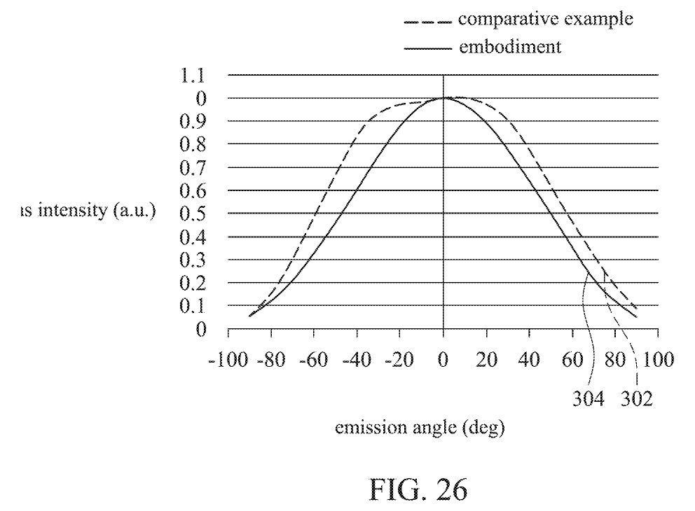

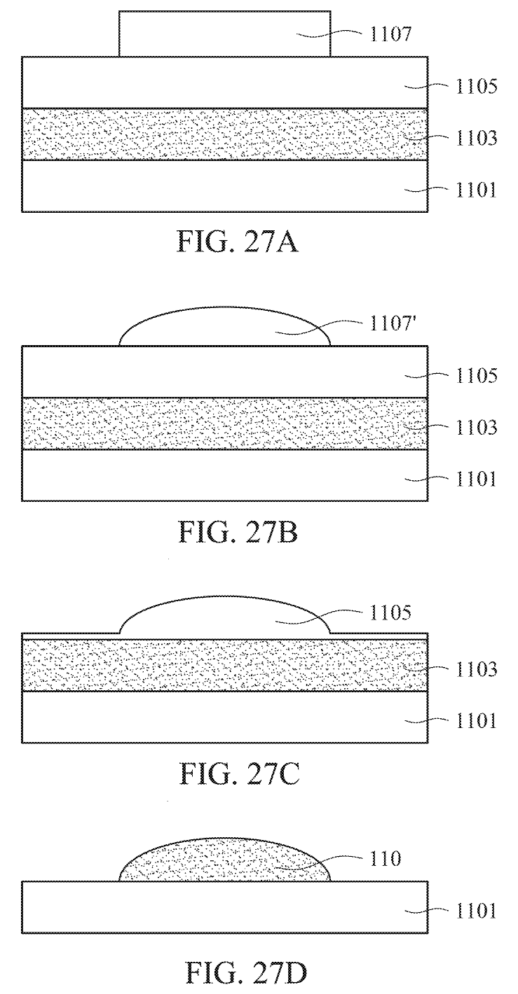

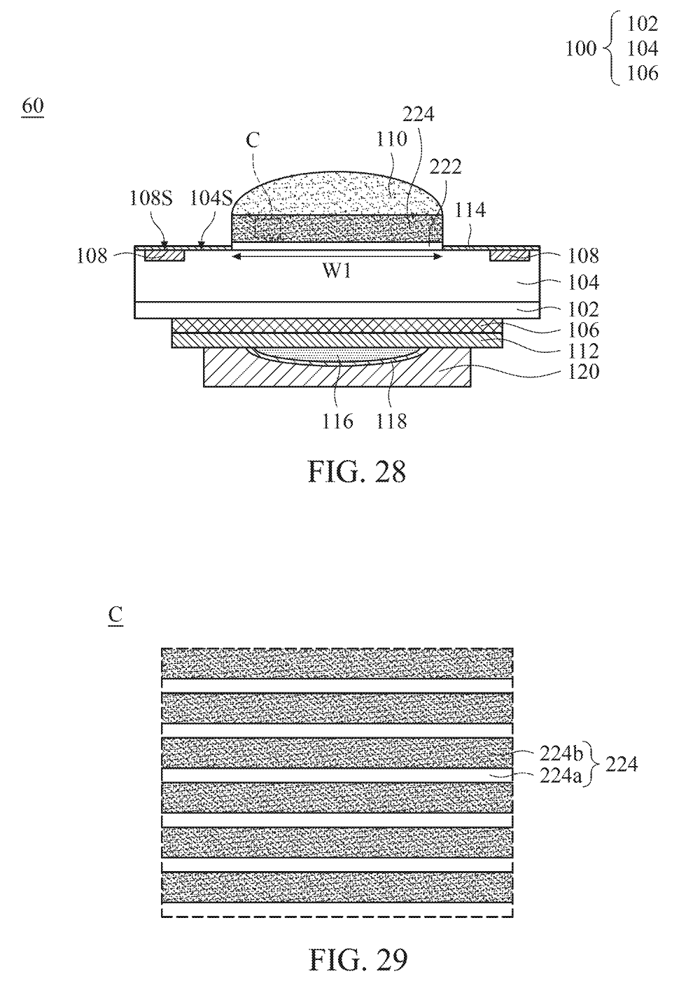

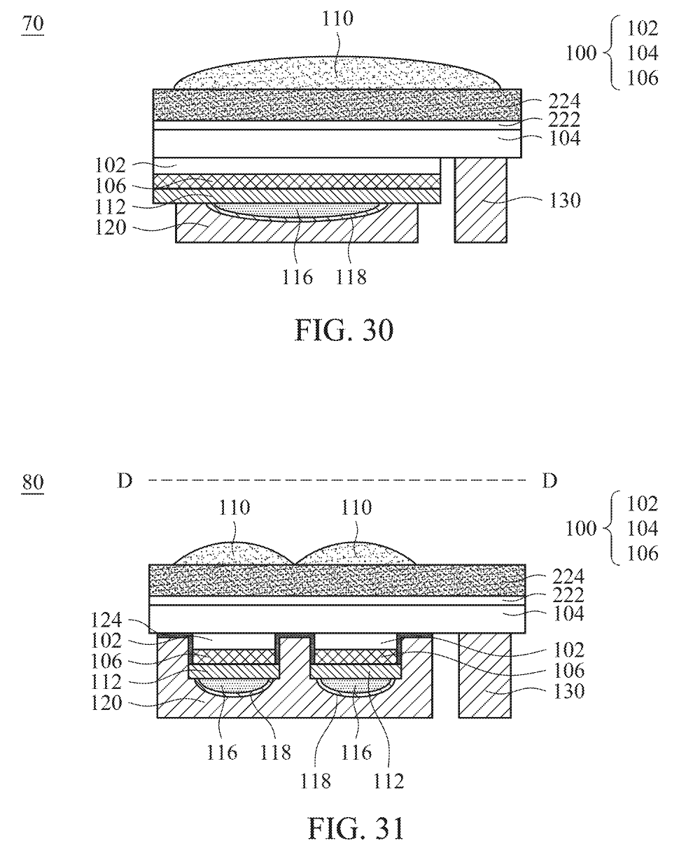

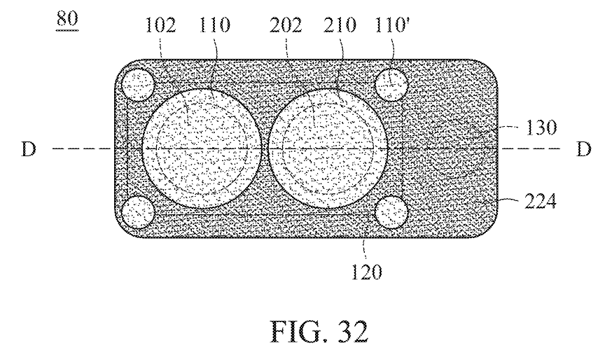

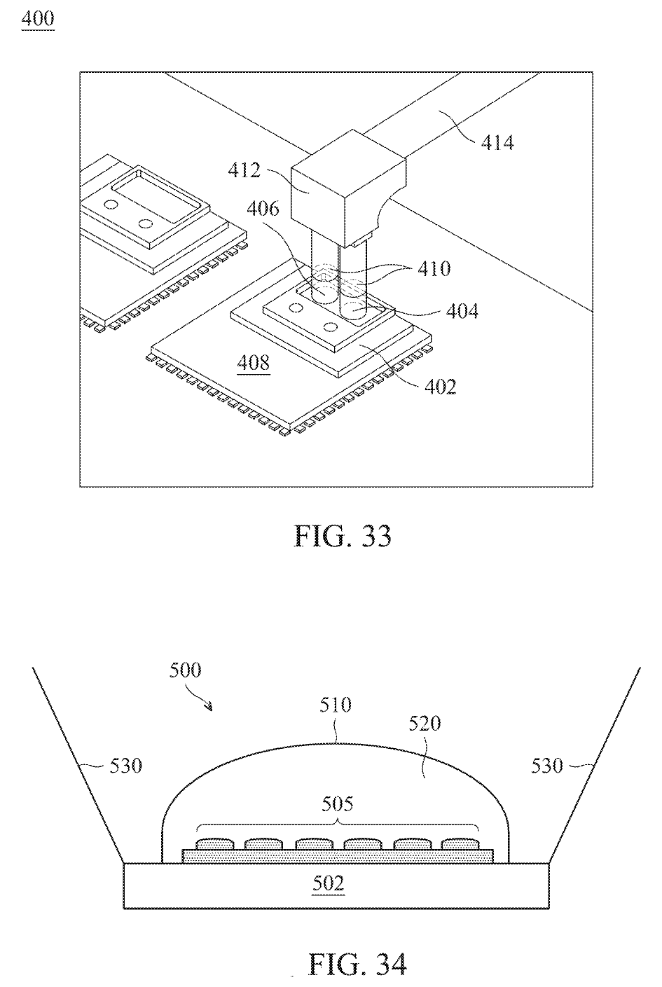

As shown in FIGS. 23 and 24, the semiconductor device 54 shown in FIG. 23 is similar to the semiconductor device 40 shown in FIG. 13, except that the plurality of first lenses 110 is located on the side of the first-type semiconductor structure 104 away from the active structure 102. In this way, each lens can be individually designed according to its position relative to the active structure 102, so that the semiconductor device 54 has a desired optical profile and emission angle. In some embodiments, the plurality of first lenses 110 is arranged in an array on the first-type semiconductor structure 104, as shown in FIG. 24. Alternatively, the plurality of first lenses 110 is arranged in a hexagonal array on the first-type semiconductor structure 104, as shown in FIG. 25. The plurality of first lenses 110 may be in contact to form a continuous distribution or not in contact to form a discontinuous distribution.

FIG. 26 illustrates the luminous intensity distribution of the semiconductor device according to an embodiment of the disclosure. The curve 304 represents the luminous intensity distribution of an embodiment of the present disclosure, which is produced by the structure shown in FIG. 23. The curve 302 represents the luminous intensity distribution of a comparative example, which is produced by the structure similar to FIG. 23 but not having the first lens 110. As shown in FIG. 26, the emission angle (full width at half maximum, FWHM) of the semiconductor device of the embodiment is approximately 23% narrower than the emission angle (FWHM) of the semiconductor device of the comparative example (approximately 120°). It can be seen that the optical profile of the semiconductor device can be optimized by the arrangement of a lens (e.g., the first lens 110) to narrow the emission angle.

FIGS. 27A to 27D illustrate the flowcharts of the manufacturing process of the first lens 110 according to some embodiments of the disclosure, and only a portion of the elements are shown in the figures. In some embodiments, a semiconductor stack with photoelectric properties is formed on a growth substrate (not shown) by metal-organic chemical vapor deposition (MOCVD), molecular beam epitaxy (MBE), hydride vapor phase epitaxy (HVPE), or physical vapor deposition (PVD). In an embodiment, the semiconductor stack includes a first lens film layer 1103 (e.g., gallium nitride) and a bottom layer 1101 (e.g., the semiconductor structure 100 in FIGS. 1 and 7-13). The growth substrate is provided for the epitaxial growth of the semiconductor stack. The growth substrate includes gallium arsenide (GaAs), sapphire (Al₂O₃), gallium nitride (GaN), silicon carbide (SiC), or aluminum nitride (AlN). The growth substrate is separated from the semiconductor stack by the transfer methods, such as laser lift-off or chemical lift-off.

Next, the first lens 110 can be formed by a deposition process, a lithography process, and an etching process. For example, a dielectric layer 1105 is first formed on the first lens film layer 1103 by a process such as plasma-enhanced chemical vapor deposition (PECVD) or atomic layer deposition (ALD). The dielectric layer 1105 can be used as an etching mask in the subsequent step for etching the first lens film layer 1103. The dielectric layer 1105 includes titanium oxide, silicon nitride, or silicon oxide. Next, a patterned photoresist layer 1107 is formed over the dielectric layer 1105 by a lithography process as shown in FIG. 27A.

Next, a thermal reflow process is provided to melt the surface of the patterned photoresist layer 1107 to form a photoresist layer 1107' with a curved (convex) profile, as shown in FIG. 27B. Then, using the photoresist layer 1107' as an etching mask, the dielectric layer 1105 is etched by an etching process to transfer the curved profile of the photoresist layer 1107' onto the underlying dielectric layer 1105 as shown in FIG. 27C. After removing the photoresist layer 1107', the dielectric layer 1105 having the curved profile is provided as an etching mask to transfer the curved profile onto the underlying first lens film layer 1103 to form the first lens 110 as shown in FIG. 27D. The above etching process may include plasma etching (PE), reactive ion etching (RIE), or electron beam etching.

In some embodiments, the formation methods of the second lens 116 and the third lens 122 may be similar to the formation method of the first lens 110 described above. The main difference is that the first lens film layer 1103 can be omitted, that is, the dielectric layer 1105 is directly deposited on the bottom layer 1101 (e.g., the second conductive layer 112 in FIG. 8 or the second-type semiconductor structure 106 in FIG. 10). In an embodiment, after etching the dielectric layer 1105 using the photoresist layer 1107' as an etching mask, the dielectric layer 1105 with a curved profile can be directly served as the second lens 116. In another embodiment, after transferring the curved profile of the dielectric layer 1105 onto the underlying bottom layer 1101, the remaining bottom layer 1101 directly serves as the third lens 122. The remaining process details are as described above and therefore will not be repeated here.

FIGS. 28, 30, and 31 illustrate the cross-sectional views of the semiconductor devices 60 , 70 , and 80 according to some embodiments of the present disclosure. Unless otherwise stated, the structural configuration and the component designations of semiconductor devices 60 , 70 , and 80 in FIGS. 28, 30, and FIG. 31 correspond to the semiconductor device 10 in FIG. 1, the semiconductor device 40 in FIG. 13, and the semiconductor device 50 in FIG. 18, respectively, the foregoing descriptions can be referred and they will not be repeated here. The semiconductor devices 60 , 70 , and 80 in FIGS. 28, 30, and FIG. 31 are similar to the semiconductor device 10 in FIG. 1, the semiconductor device 40 in FIG. 13, and the semiconductor device 50 in FIG. 18, except that the semiconductor devices 60 , 70 , and 80 further include a porous structure 224 disposed between the semiconductor structure 100 and the first lens 110 . Since the porous structure 224 includes air, the refractive index of the porous structure 224 can be reduced to confine the light emitted from the active structure 1 02 , thereby improving the emission angle and the axial light intensity of the semiconductor devices 60 , 70 , and 80 . In some embodiments, when the semiconductor device is a light-emitting diode, the porous structure 224 (serving as an upper reflector) and the second electrode 120 (serving as a lower reflector) form a resonant cavity between the upper and lower sides of the semiconductor structure 100 to provide a resonant cavity light-emitting diode (RCLED). The light emitted from the active structure 102 can be reflected back and forth between the upper and lower reflectors. The light perpendicular to the upper and lower reflectors can be enhanced, while the light not perpendicular to the upper and lower reflectors is weakened, which results in only the light having the small angle can be emitted towards the main light emitting surface. In other embodiments, the porous structure 224 can also be used as a reflector.

FIG. 29 illustrates a partially enlarged view of a semiconductor device according to some embodiments of the present disclosure. FIG. 29 illustrates an enlarged view of the region C in FIG. 28. In some embodiments, the porous structure 224 includes a plurality of non-porous layers 224a and a plurality of porous layers 224b arranged alternately. The porous structure 224 includes 5 to 20 pairs (e.g., 16, 17, 18 or 19 pairs) of alternately stacked non-porous layers 224a and porous layers 224b. In some embodiments, the porous structure 224 is formed by epitaxially growing the alternately stacked intrinsic semiconductor material layers (not shown) and doped semiconductor material layers (not shown) over the first-type semiconductor structure 104. Then, lateral etching the alternately stacked intrinsic semiconductor material layers and doped semiconductor material layers to transform the intrinsic semiconductor material layers and doped semiconductor material layers into the non-porous layers 224a and the porous layers 224b, respectively. In some embodiments, the porosity of the porous layer 224b can be from 40% to 60%, for example, 45%, 50%, 55%, etc.. The higher the porosity of the porous layer 224b is, the lower refractive index of the porous layer 224b is. In some embodiments, the refractive index of the porous layer 224b is less than the refractive index of the non-porous layer 224a. The refractive index of the porous layer 224b is less than or equal to about 1.84, for example, 1.80, 1.75, 1.70, 1.65, 1.60, 1.50, 1.45, 1.40, etc. The thicknesses of the non-porous layer 224a and the porous layer 224b can each be designed and adjusted according to their refractive index n and a quarter optical path length (𝜆/4n) of the wavelength λ of the light emitted from the active structure 102. In some embodiments, the thicknesses of the non-porous layer 224a and the porous layer 224b are not the same. The thickness of the non-porous layer 224a can be greater than or less than the thickness of the porous layer 224b. Because multiple nanometer-scale pores are formed in the porous layer 224b, the refractive index of the porous layer 224b is lower than that of the non-porous layer 224a. Thus, a Distributed Bragg Reflector is formed by alternating stacking a high-refractive-index layer (non-porous layer 224a) and a low-refractive-index layer (porous layer 224b). In some embodiments, the intrinsic semiconductor material layer and the doped semiconductor material layer include a III-V group semiconductor material, such as GaN, AlGaN, etc. The intrinsic semiconductor material layer and the doped semiconductor material layer include the same or different materials. The doping concentration of the doped semiconductor material layer may be between 1E17 atoms/cm³ and 1E19 atoms/cm³. In some embodiments, the etching process may include an electrochemical etching process.

In some embodiments, the semiconductor devices 60, 70, and 80 further include an intrinsic semiconductor layer 222 disposed between the porous structure 224 and the semiconductor structure 100. The intrinsic semiconductor layer 222 is configured to protect the underlying semiconductor structure 100 from damage during the etching process for forming the porous structure 224. In some embodiments, the intrinsic semiconductor layer 222 includes a III-V group semiconductor material, such as GaN, AlGaN, etc.

FIG. 32 illustrates a top view of a semiconductor device 80 according to some embodiments of the present disclosure. FIG. 31 is a cross-sectional view along the line D-D in FIG. 32. As shown in FIG. 32, in some embodiments, the semiconductor device 80 further includes a plurality of dummy lenses 110' disposed around the first lens 110(210). In an embodiment, the plurality of dummy lenses 110' is mirror-symmetrical with respect to a horizontal center line passing through the center of the semiconductor device 80. In another embodiment, the plurality of dummy lenses 110' is mirror-symmetrical with respect to a vertical line passing through the midpoint of the line connecting the centers of the lens 110 and the lens 210. This symmetrical arrangement facilitates the subsequent transfer processes of the semiconductor device 80, such as preventing it from flipping when transferring the semiconductor device 80 to other substrates. In some embodiments, the dummy lens 110' includes a lens-like shape, such as a circle, ellipse, or other optical element profile, but its function is not limited to the optical purposes and it can be regarded as a structural dummy structure. The purpose of the dummy lens 110' is to provide the geometric symmetry, the mechanical balance, the process stability, or the structural support during transfer.

In summary, the disclosure provides a semiconductor device with a lens. The lens arrangement optimizes the optical profile of the semiconductor device to improve the light emission angle (e.g., narrowing the light emission angle). Furthermore, the first lens and the first-type semiconductor layer include the same material, thereby reducing the optical loss caused by the Fresnel reflection and improving light extraction efficiency (LEE). Moreover, the first lens and/or the second lens can further focus or collimate the light emitted from the active structure. In addition, by setting a porous structure between the semiconductor structure and the first lens, the refractive index can be reduced, thereby improving the emission angle and the axial light intensity of the semiconductor device.

FIG. 33 is a schematic diagram illustrating a light-emitting module 400 according to other embodiments of the present disclosure. In the embodiment, the light-emitting module 400 is an optical communication device. The light-emitting module 400 is disposed in an electronic device (not shown) so that the electronic device can transmit and/or receive the optical signals. The electronic device may be a personal computer, a server, or a router. The light-emitting module 400 includes a light bundle integrated circuit 402, a light-emitting device 404, an optical signal receiver 406, a digital integrated circuit 408, a lens array 410, a connector 412, and an optical fiber 414.

The light-emitting module 400 is provided to receive the electrical signals from the electronic devices, convert the electrical signals into the optical signals, and transmits the optical signals generated by the light-emitting device 404 to a remote end via the optical fiber 414. Furthermore, the light-emitting module 400 can receive the optical signals via the optical fiber 414, convert the optical signals into the electrical signals via the optical signal receiver 406, and transmit them to the digital integrated circuit 408 for further signal processing and data decoding. The combination of the light-emitting device 404 and the lens array 410 can be any semiconductor device disclosed in the present application (e.g., the semiconductor device 50 in FIG. 18). The optical signal receiver 406 includes a photodiode array. The connector 412 is used to physically connect the optical fiber 414, the light-emitting device 404, the optical signal receiver 406, and other optical elements for the transmission of the optical signals.

FIG. 34 is a schematic diagram illustrating a light-emitting apparatus 500 according to other embodiments of the present disclosure. In the embodiment, the light-emitting apparatus 500 includes, for example, a headlight or taillight. The light-emitting apparatus 500 includes a plurality of vertical type semiconductor devices arranged alternately (e.g., a plurality of the semiconductor device 10 in FIG. 1 is arranged alternately and a plurality of the semiconductor device 20 in FIG. 10 is arranged alternately), which are collectively referred to as a light-emitting module 505. The semiconductor devices are electrically connected in series or parallel. The light-emitting module 505 is mounted on a base 502. The base 502 includes a metal core printed wire board (MCPCB) and a plurality of conductive bonding pads on the MCPCB. The MCPCB includes a metal base such as aluminum or an alloy thereof. The MCPCB also includes a thermally conductive but electrically insulating dielectric layer on the metal base. The MCPCB also includes a thin metal layer (such as copper) on the dielectric layer. In another embodiment, the base 502 may include a thermally conductive structure such as a silicon base or a ceramic base.

The light-emitting apparatus 500 further includes a diffuser cover 510 to cover the light-emitting module 505. In some embodiments, the diffuser cover 510 includes an arcuate surface or shape. In some embodiments, the arcuate surface is substantially semicircular, and the light emitted from the light-emitting module 505 is incident on the surface of the diffuser cover 510 at a substantially perpendicular angle. The diffuser cover 510 with the arcuate surface reduces the total internal reflection (TIR) of the light emitted from the light-emitting module 505. In some embodiments, the space 520 between the light-emitting module 505 and the diffuser cover 510 is filled with air. In other embodiments, the space 520 is filled with an optical-grade silicone-based adhesive material, also known as optical adhesive. In the embodiment, the fluorescent particles can be incorporated into the optical adhesive to further diffuse the light emitted from the light-emitting module 505.

The light-emitting apparatus 500 includes a reflective structure 530. The reflective structure 530 is mounted on the base 502. In some embodiments, the reflective structure includes a cup shape and is therefore also called a reflective cup. In the top view, the reflective structure 530 includes a circular, honeycomb-shaped hexagon, or other suitable shape capable of surrounding the diffuser cover 510. The reflective structure 530 is provided to reflect the light passing through the diffuser cover 510. In some embodiments, the inner surface of the reflective structure 530 is coated with a reflective film such as aluminum, silver, or an alloy thereof. In some embodiments, the sidewall of the reflective structure 530 is oblique or stepped to increase the light reflection efficiency.

It is understood that the semiconductor devices described above in the present application can also be used in other optical transmission applications and other light-emitting applications. Other optical transmission applications include, but are not limited to, digital image processing and high-speed data processing. Other light-emitting applications include, but are not limited to, instrument panel displays, projector light sources, and light sources for electronic components such as LCD TVs, LCD monitors, desktop computers, mobile phones, or laptops.

The foregoing description is merely exemplary embodiments of the present invention, and any equivalent changes and modifications made in accordance with the scope of the claims of the present invention shall fall within the scope of the present invention.

What is claimed is:

1. A semiconductor device, comprising:
a semiconductor structure, comprising:
an active structure;
a first-type semiconductor structure and a second-type semiconductor structure, respectively disposed on opposite sides of the active structure; and
a first lens, comprising an intrinsic semiconductor layer, disposed on a side of the first-type semiconductor structure away from the active structure, wherein the first lens and the first-type semiconductor structure include a same material.

2. The semiconductor device according to claim 1, wherein the first-type semiconductor structure includes n-type gallium nitride (n-GaN), and the second-type semiconductor structure includes p-type gallium nitride (p-GaN).

3. The semiconductor device according to claim 1, wherein the first lens includes undoped gallium nitride (u-GaN).

4. The semiconductor device according to claim 1, wherein in a cross-sectional view, the first lens includes a curved profile, a maximum height H of 1~5 µm, and a maximum width W of 5~15 µm.

5. The semiconductor device according to claim 1, wherein the first lens includes a first portion comprising a curved surface, a second portion comprising a flat surface, and the second portion surrounds the first portion.

6. The semiconductor device according to claim 1, wherein the first lens includes a first portion comprising a curved surface, a second portion comprising a flat surface, and the first portion surrounds the second portion.

7. The semiconductor device according to claim 1, further comprising:
a contact electrode disposed around the first lens, wherein, in a top view, the first lens has an first area, the first-type semiconductor structure has a second area, the first area is smaller than the second area.

8. The semiconductor device according to claim 7, wherein the contact electrode continuously surrounds the first lens.

9. The semiconductor device according to claim 7, further comprising:
a first conductive layer, covering the contact electrode;
a second conductive layer, disposed on a side of the second-type semiconductor structure away from the active structure; and
a second lens, covering the second conductive layer, wherein the first lens and the second lens comprise different materials.

10. The semiconductor device according to claim 9, wherein the first conductive layer extends to cover the first lens.
